(19) United States
(12) Patent Application Publication
(10) Pub. No.: US 2007/0087565 A1
(43) Pub. Date: Apr. 19, 2007

(54) Methods of forming isolation regions and structures thereof

(76) Inventors: Marcus Culmsee, Wappingers Falls, NY (US); Tae Hoon Lee, Fishkill, NY (US)

Correspondence Address: SLATER & MATSIL LLP, 17950 PRESTON ROAD, SUITE 1000, DALLAS, TX, 75252, US

(21) Appl. No.: 11/252,924

(22) Filed: Oct. 18, 2005

(51) Int. Cl. H01L 21/44; H01L 21/302

(52) U.S. Cl. 438/675; 438/691; 257/E21.583

(57) ABSTRACT

Methods of forming isolation regions for semiconductor devices and structures thereof are disclosed. A workpiece having a top surface is provided, a chemical mechanical polish (CMP) stop layer is formed over the workpiece, and a sacrificial material is formed over the CMP stop layer. The sacrificial material, the CMP stop layer, and the workpiece are patterned with a trench for an isolation region. The isolation region is filled with an insulating material, and a CMP process is used to remove the insulating material from over the top surface of the CMP stop layer. The sacrificial material is removed during the CMP process.

### TECHNICAL FIELD

The present invention relates generally to the fabrication of semiconductor devices, and more particularly to the formation of isolation regions for semiconductor devices.

### BACKGROUND

Semiconductor devices are used in a variety of electronic applications, such as personal computers, cell phones, digital cameras, and other electronic equipment, as examples. Semiconductor devices are typically fabricated by sequentially depositing insulating (or dielectric) layers, conductive layers, and semiconductive layers of material over a semiconductor substrate, and patterning the various layers using lithography to form circuit components and elements thereon. Electrical elements such as transistors, capacitors, diodes, conductive lines, and other types of elements are formed in the various material layers and are connected by wiring in conductive layers to form integrated circuits.

Isolation regions are formed on semiconductor devices to provide electrical isolation for adjacent electrical elements and devices. Isolation regions are typically formed by etching trenches in material layers, and filling in the trenches with an insulating material such as silicon dioxide (SiO₂). One type of isolation region is referred to in the art as shallow trench isolation (STI), as an example. STI is used to isolate the positive and negative channel devices of complementary metal oxide semiconductor (CMOS) devices, which use both positive and negative channel devices in complementary configurations, for example, although STI is also used as isolation in other semiconductor devices. The positive and negative channel devices of CMOS devices are typically referred to as p channel metal oxide semiconductor (PMOS) and n channel metal oxide semiconductor (NMOS) transistors. An STI region may be formed between the n well and p well of the PMOS transistor and the NMOS transistor, respectively, of a CMOS device, for example. An STI region usually extends within a workpiece or substrate by about the depth of the maximum n well and p well doping concentration, e.g., about 0.5 to 1.0 μm, for example. In other applications, deep trench (DT) isolation is used, e.g., in memory and other types of integrated circuits. Deep trench isolation typically comprises trenches filled with insulating material having a depth of greater than about 1.0 μm, for example.

A prior art STI region 118 is shown in FIG. 1. To form the STI region 118, a workpiece 102 comprising a semiconductor substrate is provided, and an oxide layer 104 is formed over the workpiece 102. A pad nitride 106 comprising silicon nitride (SiₓN_{y}) is formed over the oxide layer 104. The workpiece 102, oxide layer 104, and pad nitride 106 are patterned using lithography with the desired shape of the trench for the STI region. Liners 110 and 112 comprising an oxide and a nitride, respectively, may be formed over the pad nitride 106 and the trench pattern, as shown. An insulating material 114 such as SiO₂ is deposited over the pad nitride 106 to fill the trench. Excess insulating material 114 is removed from the top surface of the pad nitride 106 using a chemical mechanical polish (CMP) process.

Some CMP processes are adapted to stop on the pad nitride 106, which has a slower removal rate than the insulating material 114, for example, and thus, they are referred to in the art as “selective” CMP processes. However, selective CMP processes utilize slurries that include an abrasive, which causes dishing of the trench oxide 118 after the pad nitride 106 is reached, e.g., as shown at 116. The term “dishing” refers to an excessive amount of the insulating material 114 being removed below the top surface of the pad nitride 106, for example. Dishing of the insulating material 114 below the pad nitride 106 top surface is undesirable because later when the pad nitride 106, oxide layer 104 and insulating material 114 are removed from over the top surface of the workpiece 102 using a wet etch, for example, the dishing 116′ pattern (shown in phantom in FIG. 1) remains in the insulating material 114 beneath the top surface of the workpiece 102, degrading the isolation between semiconductor devices, e.g., within the workpiece 102.

A prior art method of circumventing the dishing that can occur when CMP processes with abrasive slurries are used, is the use of fixed abrasive CMP pads. With fixed abrasive CMP pads, abrasives are not included in the slurry, to avoid the abrasives entering into trenches. Rather, with fixed abrasive CMP pads, the abrasive medium is attached or fixed to the CMP pad. However, a fixed abrasive CMP pad is problematic in that it can cause micro-scratches on the surface of the pad nitride 106, and it has a high cost of ownership, e.g., fixed abrasive CMP pads are expensive and need frequent replacement. Therefore, selective slurry processes tend to be used more often in STI region formation.

FIG. 2 shows a prior art drawing of a cross-sectional view of several STI regions 118a and 118b formed on a workpiece 102. Often, dishing 116′ occurs on some STI regions 118a, as shown in region 120, but not in other STI regions 118b, as shown in region 122. Wider STI regions 118a have a tendency to exhibit dishing 116′ more often and more severely than narrower STI regions 118b, for example. Typically, the wider the STI region trench, the more severe the dishing 116′ is. The prevention of dishing 116′ for all STI regions 118a and 118b across the surface of a workpiece 102 is desired.

In general, in semiconductor device 100 manufacturing, a term referred to as “step height” is typically used to define the amount of topography across a surface of a workpiece 102. A minimum and maximum step height is typically defined for integrated circuits manufactured on a wafer, for example. In semiconductor devices having STI regions 118a and 118b, step height is anticipated for the STI regions, wherein the top surfaces of the STI regions such as 118b extend above the top surface of a workpiece 102 (not shown). The range for step height for semiconductor devices 100 is typically limited to a specific amount for a particular technology node. Step height of STI regions varies across a surface of a workpiece, and is dependent on various parameters, such as the pad nitride 106 (see FIG. 1) thickness, the amount of insulating material 114 used to form the STI regions 118a and 118b, and etch processing variations, as examples, although step height may also be caused by other parameters and processes. Protrusion and dishing caused by prior art CMP processes show a convex and concave shape in the topography and are dependent on the trench width, but step height typically does not depend on trench width, for example. While a limited amount of step height is allowable, divot formation due to CMP processes is undesirable, because isolation is reduced between features and active areas.

Thus, what are needed in the art are improved methods for forming isolation structures for semiconductor devices, and structures thereof, wherein dishing of STI regions is reduced or eliminated.

### SUMMARY OF THE INVENTION

These and other problems are generally solved or circumvented, and technical advantages are generally achieved, by preferred embodiments of the present invention, which provide novel methods of forming STI regions of semiconductor devices.

In accordance with a preferred embodiment of the present invention, a method of forming an isolation region for a semiconductor device includes providing a workpiece, and forming a CMP stop layer over the workpiece, the CMP stop layer having a top surface. A sacrificial material is formed over the CMP stop layer. At least the sacrificial material, the CMP stop layer, and the workpiece are patterned to form at least one trench in the sacrificial material, the CMP stop layer, and the workpiece. At least a first portion of the at least one trench is filled with an insulating material, and the workpiece is polished to remove the insulating material from over the top surface of the CMP stop layer. The sacrificial material is removed from over the top surface of the CMP stop layer during the polishing process.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a prior art semiconductor device having an STI region that exhibits dishing;

FIG. 2 shows a cross-sectional view of several STI regions formed across a surface of a semiconductor workpiece, wherein wider STI regions exhibit dishing, and narrower STI regions do not exhibit dishing;

FIGS. 3 through 5 show cross-sectional views of a method of forming an STI region in accordance with a preferred embodiment of the present invention at various stages of manufacturing;

FIGS. 6 through 8 show cross-sectional views of a method of forming an STI region at various stages of manufacturing in accordance with another preferred embodiment of the present invention; and

FIG. 9 shows several STI regions formed across a surface of a workpiece in accordance with embodiments of the present invention, wherein the top surface of the insulating material of the STI regions is either coplanar with a top surface of the workpiece, or is slightly raised above the top surface of the workpiece.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely, in the formation of STI regions for CMOS transistors. The invention may also be applied, however, to other isolation structures and methods of forming thereof for semiconductor devices. Only one STI region is shown in each of the figures; however, there may be many, e.g., hundreds or thousands of STI regions formed on a semiconductor device, for example. Embodiments of the present invention are shown and described with reference to shallow isolation regions; however, alternatively, deep trench isolation may also be formed by the novel methods of the present invention, for example.

A method of manufacturing an STI region 240 will next be described. FIGS. 3 through 5 show cross-sectional views of a method of forming an STI region 240 of a semiconductor device 200 at various stages of manufacturing in accordance with a preferred embodiment of the present invention. First, a workpiece 202 is provided, as shown in FIG. 3. The workpiece 202 may include a semiconductor substrate comprising silicon or other semiconductor materials covered by an insulating layer, for example. The workpiece 202 may also include other active components or circuits, not shown. The workpiece 202 may comprise silicon oxide over single-crystal silicon, for example. The workpiece 202 may include other conductive layers or other semiconductor elements, e.g., transistors, diodes, etc. Compound semiconductors, GaAs, InP, Si/Ge, or SiC, as examples, may be used in place of silicon. The workpiece 202 may also comprise bulk Si, SiGe, Ge, SiC, or a silicon-on-insulator (SOI) substrate, as examples.

An oxide layer 204 is formed over the workpiece 202. The oxide layer 204 may comprise about 50 A of silicon dioxide (SiO₂), for example, although the oxide layer 204 may alternatively comprise other materials and dimensions.

A nitride layer 206 is formed over the oxide layer 204. The nitride layer 206 is also referred to herein as a pad nitride or a CMP stop layer. The pad nitride 206 may comprise about 600 to 800 Å of silicon nitride (SiₓN_{y}), for example, although the pad nitride 206 may alternatively comprise other materials and dimensions. The pad nitride 206 preferably comprises a material that will function as a CMP stop layer during a CMP process to remove excess insulating material from over the top surface of the pad nitride 206, to be described further herein. The nitride layer 206 is preferably resistant to removal during a CMP process, for example.

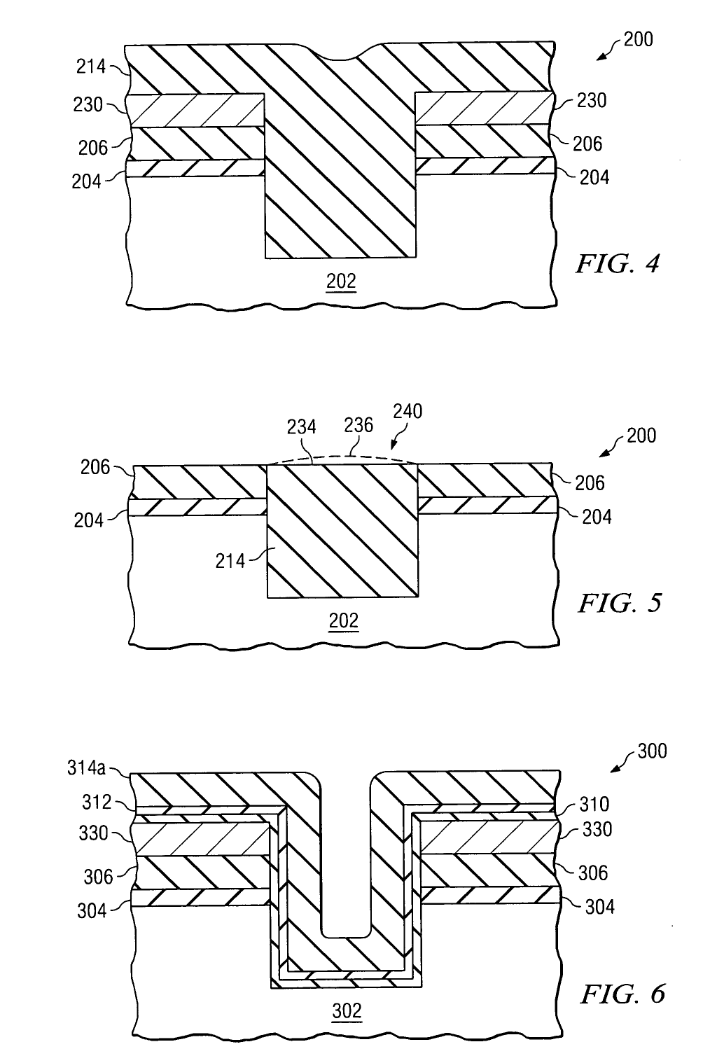

A sacrificial material 230 is formed over the nitride layer 206. The sacrificial material 230 preferably comprises a material that is removed more rapidly than the pad nitride 206 is removed, e.g., in a subsequent CMP process. The sacrificial material 230 also preferably comprises a material that is removed more rapidly than the insulating fill material (see insulating material 214 in FIG. 4) for the STI trench, to be described further herein. The sacrificial material 230 preferably comprises a semiconductor material including at least one dopant. The at least one dopant preferably comprises boron (B), phosphorous (P), other dopant types, or combinations thereof. In one embodiment, for example, the sacrificial material 230 preferably comprises boron phosphate silicate glass (BPSG), as an example, although alternatively, other materials may be used. BPSG is often used as a dielectric material for the upper levels of semiconductor devices, and thus, it is readily available in semiconductor device fabrication facilities, advantageously. BPSG has a lower melting point than SiO₂ and flows readily, to evenly coat the surface of the nitride layer 206, for example. The sacrificial material 230 may also comprise boron silicate glass (BSG) or phosphate silicate glass (PSG), as examples. Doped silicon oxides typically have a higher removal rate in a CMP process than undoped silicon oxide, for example; thus, preferably the sacrificial material 230 comprises a doped silicon oxide material. The sacrificial material 230 preferably comprises a thickness of about 400 Å, for example, although alternatively, other thicknesses may be used, such as about 1,000 Å or less.

An optional hard mask 232, shown in phantom in FIG. 3, may be formed over the sacrificial layer 232. The hard mask 232 may comprise tetra ethyl oxysilane (TEOS) or other insulating materials, for example. The hard mask 232 may comprise a thickness of about 100 nm, for example, although alternatively, the hard mask 232 may comprise other dimensions.

A layer of photoresist (not shown) is deposited over the top surface of the sacrificial layer 230, or over the hard mask 232, if a hard mask 232 is used. The layer of photoresist is patterned with the desired pattern for the STI region, for example, using lithography. The layer of photoresist is then used as a mask to pattern the sacrificial layer 230, the pad nitride 206, the oxide layer 204, and the workpiece 202 to form a trench, as shown in FIG. 4. The trench comprises sidewalls and a bottom surface. If a hard mask 232 is used, the layer of photoresist is used to pattern the hard mask 232, and then the hard mask 232 or the hard mask 232 and the layer of photoresist are used as masks while the sacrificial layer 230, the pad nitride 206, the oxide layer 204, and the workpiece 202 are etched to form the STI region trench. Again, only one trench is shown in FIG. 4; however, there may be many trenches formed across the surface of the workpiece 202 simultaneously, for example.

The etch process to form the trench may comprise a reactive ion etch (RIE), for example, although alternatively, other etch processes may be used. The etch process is continued for a predetermined period of time to etch the workpiece 202 by a predetermined amount or distance within the workpiece 202, for example. The layer of photoresist and optional hard mask 232 are then removed.

The STI region trench formed may comprise a width of about 500 nm or greater, although in some technologies, STI region trenches may comprise about 500 nm or less, as examples. The STI region trenches may comprise a width of about 50 nm or greater, in some embodiments, for example. The STI region trenches may comprise the same width across the surface of the workpiece 202, although alternatively, the STI region trenches may comprise varying widths across the surface of the workpiece 202, for example. The STI region trenches may extend into the workpiece 202 by about 3,000 Å or greater. In one embodiment, for example, the STI region trenches extend below a top surface of the workpiece 202 by about 4,300 Å, for example.

Next, the STI region trench is at least partially filled with an insulating material 214, as shown in FIG. 4. The fill process may comprise depositing a spin-on-glass (SOG). As another example, the fill process may comprise a conformal deposition of an insulator such as tetra ethyl oxysilane (TEOS), using a high aspect ratio fill process such as HARP™ by Applied Materials, Inc. However, alternatively, other processes and insulating materials may be used to fill the STI trench. As examples, the insulating material 214 may comprise SiO₂ deposited by a chemical vapor deposition (CVD) process, such as TEOS deposited by Sub Atmospheric pressure CVD (SACVD) or SiH₄/ozone high density plasma (HDP) CVD. In the embodiment shown in FIGS. 3 through 5, the STI region trench may be completely filled with insulating material 214 in a single fill step, using HARP™, for example. The insulating material 214 may extend above the sacrificial material 230 by about 6,000 Å, for example.

The insulating material 214 preferably comprises a first removal rate during a CMP process. The sacrificial material 230 preferably comprises a second removal rate during a CMP process, wherein the second removal rate is faster or greater than the first removal rate. The second removal rate is preferably at least 5 times faster than the first removal rate, for example. As another example, the second removal rate is preferably 10 times or greater faster than the first removal rate.

As an example, if the insulating material 214 comprises SiO₂ deposited by chemical vapor deposition (CVD), e.g., and the sacrificial material 230 comprises BPSG, the sacrificial material 230 may be removed or polished about 10 times faster than the insulating material 214. The speed of the CMP process depends on several factors, such as the table speed, head speed, down force, slurry flow, pad material, and type of slurry used, as examples. The nitride layer 206 is preferably thinner than prior art pad nitride layers, in some embodiments of the present invention, to allow for the increased thickness due to the sacrificial material layer 230, for example, to avoid increasing the aspect ratio of the STI region trenches. The insulating material 214 is preferably removed highly selectively to the nitride layer 206, so that the nitride layer 206 may be used as a CMP stop. One advantage of embodiments of the present invention is the ability to have a thinner nitride layer 206 or pad nitride layer, so that the removal of the nitride layer 206 in a later processing step is made easier and requires less time.

A CMP process is used to remove the excess insulating material 214 from above the top surface of the nitride layer 206, leaving the structure shown in FIG. 5. The CMP process is adapted to stop when the nitride layer 206 is reached, e.g., because nitride is removed at a much slower rate than the insulating material 214. The sacrificial material 230 is also removed from over the top surface of the CMP stop layer 206 during the CMP process. The CMP process preferably includes an abrasive in the slurry, in one embodiment. In another embodiment, an abrasive may not be included in the slurry, for example.

Because of the presence of the sacrificial material 230, advantageously, dishing of the insulating material 214 below the top surface of the nitride layer 206 during the CMP process is prevented. When the CMP process initially begins, only the insulating material 214 is removed. However, when the sacrificial material 230 is reached, then the CMP process removes the sacrificial material 230 simultaneously with the insulating material 214 within the trench. Because the sacrificial material 230 is removed at a faster rate than the insulating material 214 is removed, dishing of the insulating material 214 is prevented. The CMP process is stopped when the nitride layer 206 is reached, or shortly thereafter, for example.

After the CMP process, the insulating material 214 may be coplanar with the top surface of the nitride layer 206, as shown at 234 in FIG. 5. Alternatively, after the CMP process, the insulating material 214 may protrude above the top surface of the nitride layer 206, as shown in phantom at 236, because the insulating material 214 is removed at a slower rate than the sacrificial material 230 is removed.

In some embodiments, the wider the STI region 240 is, the greater the protrusion of the insulating material 214 above the top surface of the nitride layer 206 will be, for example. The protrusion of the insulating material 214 may extend above the top surface of the nitride layer 206 by about 10 to 50 Å due to the CMP process using the novel sacrificial material 230 described herein in some embodiments, for example. In other embodiments, the insulating material 214 preferably extends on at least some of the STI regions 240 by an amount greater than about 50 Å or less above the top surface of the nitride layer 206 due to the CMP process using the novel sacrificial material 230 described herein, for example. In other embodiments, all of the STI regions 240 have an insulating material 214 that is coplanar with the top surface of the nitride layer 206, for example, due to the CMP process using the novel sacrificial material 230 described herein.

In some embodiments, ideally, all of the sacrificial material 230 is removed during the CMP process. However, in other embodiments, a substantial amount of the sacrificial material 230 is removed, and a small amount of sacrificial material 230 residue remains residing over the nitride layer 206. For example, due to non-uniformity of the workpiece 202, there may be sacrificial material 230 residue on some portions of the workpiece 202 and no sacrificial material 230 residue on other portions of the workpiece 202. If left remaining, the sacrificial material 230 residues would mask the pad nitride 206 during the wet etch process to remove the nitride layer 206, which may comprise phosphoric acid, for example. This sacrificial material 230 residue is preferably removed using a separate etch process, or as part of a subsequent etch process to remove the nitride layer 206. If a separate etch process is used to remove the sacrificial material 230 residue, preferably an etch process with a relatively high degree of selectivity is used, e.g., the etch process etches the sacrificial material 230 more than the insulating material 214 of the STI regions. The separate etch process for removing the sacrificial material 230 residue preferably comprises diluted HF, as an example, although other chemicals may also be used.

Next, the nitride layer 206 and a portion of the insulating material 214 are removed, leaving a structure such as the one shown in FIG. 9. The etch process preferably comprises a wet etch or “deglaze” process, for example, although other etch processes may also be used. If a separate etch process is not used to remove the sacrificial material 230 residue, preferably the etch process to remove the nitride layer 206 comprises an etch process that is not highly selective, e.g., with respect to the insulating material 214 of the STI regions.

Because the sacrificial material 230 also has a higher wet etch rate than the insulating material 214 in the trench, the deglaze process can be less aggressive, according to the amount of insulating material 214 removed in the trench area. Therefore, in accordance with embodiments of the present invention, the thickness of the pad nitride 206 can be reduced, resulting in the additional sacrificial layer 230 not dramatically increasing the aspect ratio of the trenches to be etched, for example.

The amount of insulating material 214 removed during the wet etch process, the thickness of the pad nitride 206, and the time of the etch process, as examples, determine the step height of the STI regions across the workpiece 202. The step height is the distance d₁ or d₂ between the top surface of the STI regions and the top surface 250 and 250′ (shown in phantom), respectively, of the workpiece 202. In some areas, the step height d₂ may be greater than in other areas such as d₁, due to differences in the pad nitride 206 thickness or other parameters, for example.

In one embodiment, for example, if a separate selective wet etch process after the CMP process is used to remove the sacrificial material 230 residue, because the sacrificial material 230 has a higher wet etch rate than the insulating material 214 in the trench, which may comprise HDP-oxide or SACVD oxide, the sacrificial material 230 residues over the pad nitride left remaining after the CMP process can be removed completely, while only a very small amount of insulating material in the trench area is removed due to the different etch rate. Therefore the pad nitride 206 thickness can be reduced while maintaining the step height. The step height range is needed to compensate for the non-uniformity that is exhibited over the entire surface of the workpiece 202, due to the various processes involved in the STI integration scheme.

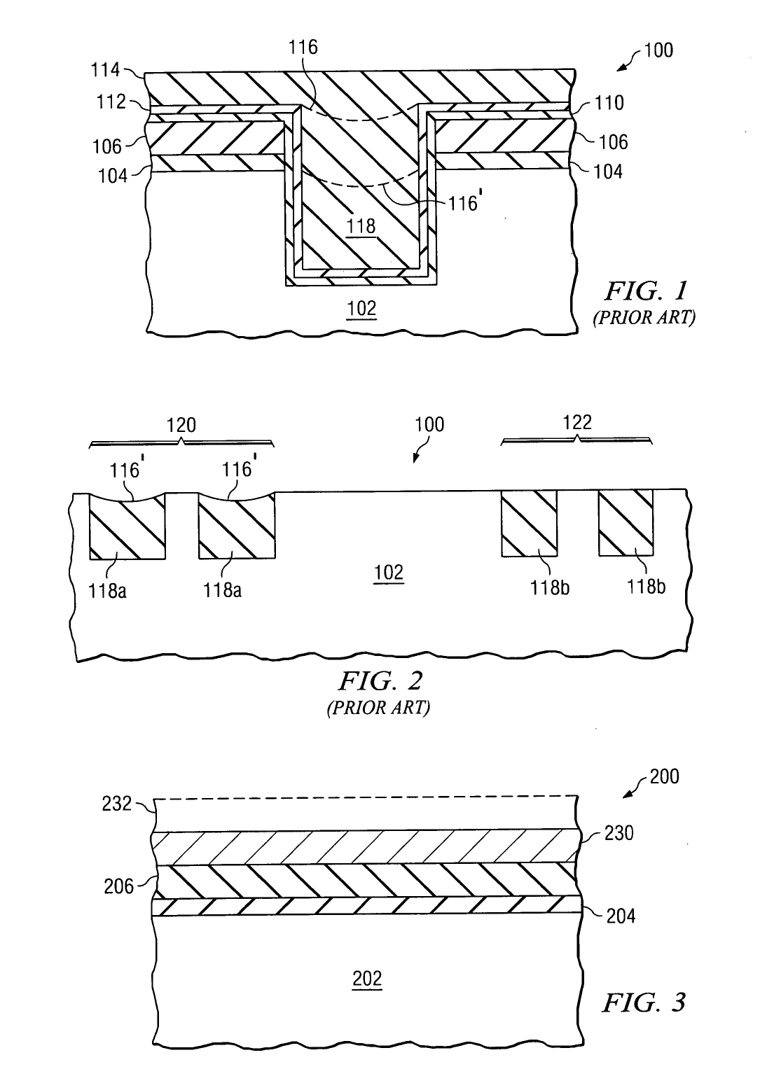

The smallest allowable value for the step height is preferably zero, wherein the trench filled with insulating material 214 is coplanar with the surface of the workpiece 202. As described with reference to FIG. 1, prior art CMP processes cause the formation of divots in the top surface of the insulating material, which is undesirable, so that the smallest value for the step height was not able to be achieved (e.g., a step height of less than zero, or a divot, was achieved in prior art processes). Embodiments of the present invention advantageously provide the capability to achieve the smallest value for step height for a particular technology node, by the use of the sacrificial material 230 during the CMP process.

The largest allowable value for step height depends on the technology node. As an example, in advanced logic fabrication (e.g., 65 nm), the maximum allowable step height may be about 300 Å. Advantageously, the largest allowable value for step height for other technology node that embodiments of the invention are implemented in is also achievable.

Again, the etch process to remove the nitride layer 206 may comprise an HF-containing solution, and the etch process is preferably adapted to substantially conformally remove the material layers 214, 206, and 204 from over a top surface of the workpiece 202. Because the insulating material 214 is evenly removed, the coplanarity (e.g., shown at 234 in FIG. 5) of the insulating material 214 with the top surface of the nitride layer 206 is transferred downward so that the insulating material 214 is, in an optimum case, coplanar with the top surface of the workpiece 202, as shown in FIG. 9 at 234′, for region 222 comprising STI regions 240c. Again, over the entire surface or diameter of the workpiece 202, the existence of a certain step height, as described above, needs to be taken into consideration. If an excess amount of the insulating material 204 remains exceeding the top surface of the nitride layer 206 after the CMP process, as shown at 236 in FIG. 5, then the shape of the insulating material 204 is retained during the etch process to remove the nitride layer 206. For example, a portion of the top surface of the insulating material 204 resides above a top surface of the workpiece 202, as shown at 236a′ and 236b′ for regions 220 and 221 comprising STI regions 240a and 240b, respectively, in FIG. 9.

Again, the wider the STI regions 240a, 240b, and 240c are, the greater the protrusion of the insulating material 214 will extend above the top surface of the workpiece 202 will be, for example, due to the CMP process, because there is more sacrificial material 230 proximate the wider STI regions 240a, for example, to slow the CMP process. The protrusion of the insulating material 214 may extend above the top surface of the workpiece 202 due to the CMP process by about 10 to 50 Å in some embodiments, and in other embodiments, preferably extends on at least some of the STI regions 240a or 240b in regions 220 and 221, respectively, by an amount greater than about 50 Å or less due to the CMP process, greater above the top surface workpiece 202, for example. In other embodiments, at least some of the STI regions such as STI regions 240c shown in region 222 have an insulating material 214 that is coplanar with the top surface of the workpiece 202, for example. The amount of the protrusion contributes to the step height across the workpiece 202, and preferably the step height ranges from zero to a predetermined amount. The predetermined amount varies according to the technology node, and may comprise about 300 Å, in one embodiment.

Because dishing of the insulating material 214 is avoided in accordance with embodiments of the present invention, better isolation is provided for the semiconductor device 200.

FIGS. 6 through 8 show cross-sectional views of a method of forming an STI region at various stages of manufacturing in accordance with another preferred embodiment of the present invention. Like numerals are used in FIGS. 6 through 8 as were used in the previous figures.

In this embodiment, after the STI region trenches are formed, an optional liner 310/312 is formed within the trenches and over the top surface of the sacrificial material 330. The liner 310/312 is disposed over the sidewalls and bottom surface of the trench. The liner 310/312 may comprise a first liner 310 comprising an oxide disposed within the trench (e.g., the trench formed in the workpiece 302, oxide layer 304, nitride layer 306, and sacrificial layer 330). The first liner 310 preferably comprises a thickness of about 7 nm or less. The liner 310/312 may include a second liner 312 comprising a nitride and having a thickness of about 13 nm or less disposed over the first liner 310. The liner 310/312 may be formed by, after forming the STI region trenches, depositing the first liner 310, and depositing the second liner 312 over the first liner 310, for example. The liners 310 and 312 may alternatively comprise other materials and dimensions, for example.

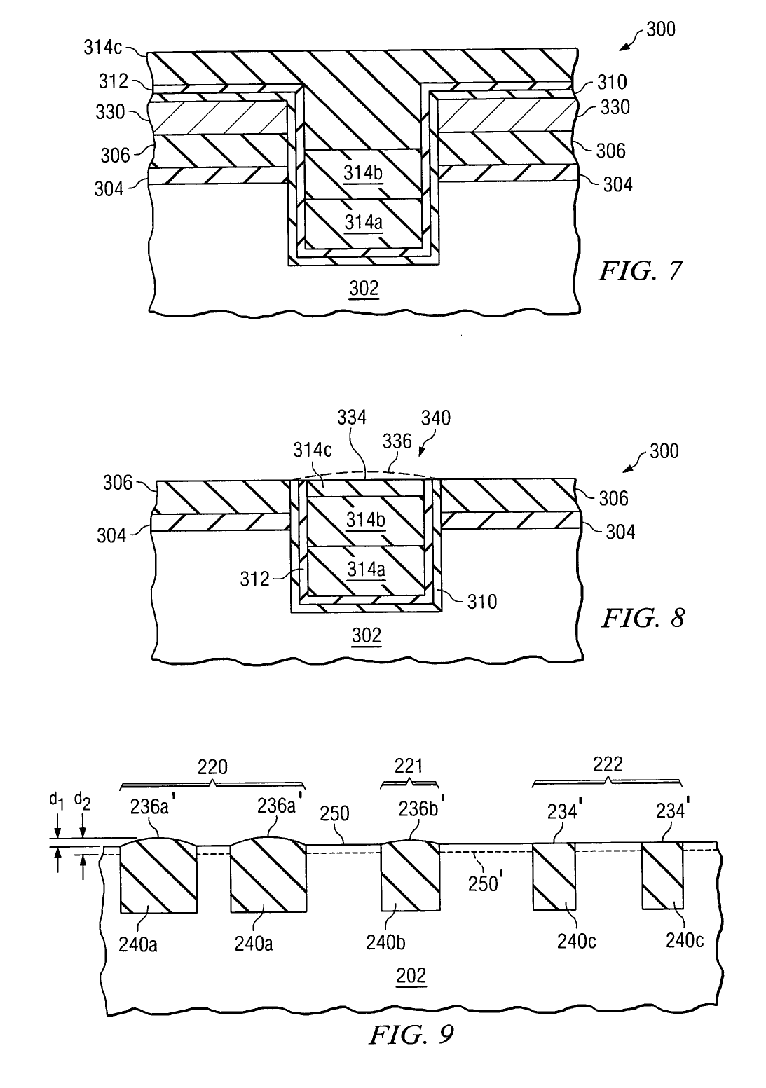

In this embodiment, the STI region trenches are filled in two or more steps. For example, preferably, at least ¼ of the depth of the trench is filled with a first insulating material layer 314a, as shown in FIG. 6. A wet etch process or other etch process may be used to remove the insulating material 314a from the upper rim of the trench, where deposition tends to be faster, to avoid forming voids within the trench. As the first insulating material 314a is deposited, excess material may form at the upper corners of the trenches, due to a higher growth rate at the edges. To avoid forming voids or air gaps within the trenches, the insulating material 314a build-up at the top of the trenches is preferably removed, for example. The first insulating material 314a may also be removed from the top surface of the liner 310/312 during this etch process. Then, at least a second portion of the trench is filled with a second insulating material 314b, as shown in FIG. 7. Again, the second insulating material 314b may be etched to ensure that the trenches are completely filled with insulating material, for example. A third portion of the trench is then filled with a third insulating material 314c, as shown in FIG. 7. Because a liner 310/312 is used, the liner 310/312 protects the material layers 302, 304, 306, 330 during the fill and etch steps. A CMP process is then used to remove excess third insulating material 314c from the top surface of the nitride layer 306, also removing the sacrificial material 330 in the CMP process, leaving the structure shown in FIG. 8. Two or more layers of insulating material 314a, 314b, 314c, e.g., three or more, may be required to fill the trench, depending on the dimensions of the trench and the material layer 304/306/330 thickness, for example.

The insulating material layers 314a, 314b, and 314c preferably comprise the same material, such as SiO₂, in one embodiment. However, in other embodiments, the insulating material layers 314a, 314b, and 314c may comprise different materials, for example. The pad nitride 306 and oxide layer 304 are removed, and the shape 334 or 336 of the top surface of the insulating material 314c is transferred to the resulting top surface, e.g., within insulating material layer 314b proximate the top surface of the workpiece 302, as shown in FIG. 9 at 234′, 236a′, or 236b′.

FIG. 9 shows several STI regions 240 (e.g., STI regions 240a, 240b, and 240c) formed across a surface of a workpiece 202 in accordance with embodiments of the present invention, wherein the STI regions 240a, 240b, and 240c are either coplanar with a top surface of the workpiece 202 after the removal of the pad nitride, as shown in STI region 240c in region 222 at 234′, or the STI regions 240a and 240b are slightly raised above the top surface of the workpiece 202, as shown in regions 220 and 221, respectively, at 236′. Advantageously, dishing of the STI regions 240a, 240b, and 240c is prevented, by the use of the novel sacrificial material 230. Wider STI regions 240a may tend to have more protrusion of the insulating material 214 above the top surface of the workpiece 202 than thinner STI regions 240c, which may have either a small protrusion, or rather, in some embodiments, thinner STI regions 240c may have no protrusion at all and may be coplanar with the workpiece 202, for example.

In accordance with one preferred embodiment of the present invention, a method of forming an isolation region for a semiconductor device includes providing a workpiece, the workpiece having a first top surface, and forming a pad nitride layer over the workpiece, the pad nitride layer having a second top surface. A sacrificial material is formed over the pad nitride layer, the sacrificial material having a first removal rate. At least the sacrificial material, the pad nitride layer, and the workpiece are patterned to form at least one trench in the sacrificial material, the pad nitride layer, and the workpiece. At least a first portion of the at least one trench is filled with an insulating material, the insulating material having a second removal rate, wherein the second removal rate of the insulating material is slower than the first removal rate of the sacrificial material. The workpiece is polished to remove the insulating material from over the top surface of the pad nitride layer, wherein at least a substantial amount of the sacrificial material is removed from over the top surface of the pad nitride layer during the polishing process. At least the pad nitride layer and a portion of the insulating material are removed. The insulating material comprises a third top surface after removing at least the pad nitride layer and the portion of the insulating material, wherein no portion of the third top surface of the insulating material resides beneath the first top surface of the workpiece.

In accordance with another preferred embodiment of the present invention, a semiconductor device includes a workpiece, the workpiece having a first top surface, and a plurality of trenches formed in the workpiece. An insulating material is disposed in the plurality of trenches. The insulating material comprises a second top surface. The insulating material in the plurality of trenches comprises a plurality of STI regions, wherein no portion of the second top surface of the insulating material resides below the first top surface of the workpiece.

Advantages of embodiments of the invention include providing novel methods of forming STI regions 240/240a/240b/240c/340 of semiconductor devices 200/300. The sacrificial material 230/330 prevents dishing of the STI regions 240/240a/240b/240c/340 during CMP processes used to remove excess insulating material 214/314c from over the top surface of a nitride layer 206/306. A step height for the STI regions 240/240a/240b/240c/340 of zero to a predetermined amount is achievable. The STI regions 240/240a/240b/240c/340 are coplanar with the workpiece 202/302 or protrude slightly above the workpiece 202/302, providing improved electrical isolation for devices formed in the workpiece. The thickness of the sacrificial material 230/330 may be selected for a particular semiconductor device 200/300 design, e.g., according to material layer thicknesses and trench depth. The STI region trenches may be lined with an optional liner 310/312 before filling them with insulating material 314a, 314b, and 314c, allowing for a multi-step fill process, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an isolation region for a semiconductor device, the method comprising:
providing a workpiece;
forming a chemical mechanical polishing (CMP) stop layer over the workpiece, the CMP stop layer having a top surface;
forming a sacrificial material over the CMP stop layer;
patterning at least the sacrificial material, the CMP stop layer, and the workpiece to form at least one trench in the sacrificial material, the CMP stop layer, and the workpiece;
filling at least a first portion of the at least one trench with an insulating material; and
polishing the workpiece to remove the insulating material from over the top surface of the CMP stop layer, wherein the sacrificial material is removed from over the top surface of the CMP stop layer during the polishing process.

2. The method according to claim 1, wherein polishing the workpiece comprises a CMP process, wherein filling at least a portion of the at least one trench with an insulating material comprises filling at least a portion of the at least one trench with an insulating material having a first removal rate during the CMP process, wherein forming the sacrificial material comprises forming a material having a second removal rate during the CMP process, and wherein the second removal rate is greater than the first removal rate.

3. The method according to claim 2, wherein the CMP process comprises a slurry including an abrasive.

4. The method according to claim 1, wherein forming the sacrificial material comprises forming a semiconductor material, the semiconductor material comprising at least one dopant.

5. The method according to claim 4, wherein the at least one dopant comprises boron (B), phosphorous (P), other dopant types, or combinations thereof.

6. The method according to claim 1, wherein the top surface of the CMP stop layer comprises a first top surface, wherein the insulating material comprises a second top surface after polishing the workpiece, and wherein no portion of the second top surface of the insulating material is below the first top surface of the CMP stop layer after polishing the workpiece.

7. The method according to claim 6, wherein the workpiece comprises a third top surface, further comprising removing the CMP stop layer and a portion of the insulating material from over the workpiece, wherein the insulating material comprises a fourth top surface after removing the CMP stop layer and the portion of the insulating material, wherein no portion of the fourth top surface of the insulating material is below the third top surface of the workpiece.

8. The method according to claim 1, wherein patterning at least the sacrificial material, the CMP stop layer, and the workpiece comprises forming a plurality of trenches within the workpiece, wherein the insulating material within the plurality of trenches forms a plurality of shallow trench isolation (STI) regions within the workpiece, wherein the plurality of STI regions comprises a step height above a top surface of the workpiece, wherein the step height for each of the plurality of STI regions ranges from zero to a predetermined amount.

9. The method according to claim 8, wherein the predetermined amount comprises 300 Angstroms.

10. The method according to claim 1, wherein a top surface of the insulating material is at least coplanar to the top surface of the CMP stop layer, or wherein the top surface of the insulating material protrudes above the top surface of the CMP stop layer by a predetermined amount due to the polishing process, after polishing the workpiece to remove the insulating material from over the top surface of the CMP stop layer.

11. The method according to claim 10, further comprising removing the CMP stop layer and a portion of the insulating material from over the workpiece, wherein a top surface of the insulating material is at least coplanar to a top surface of the workpiece, or wherein the top surface of the insulating material protrudes above the top surface of the workpiece by a predetermined step height, after etching away the CMP stop layer and the portion of the insulating material.

12. A method of forming an isolation region for a semiconductor device, the method comprising:
providing a workpiece, the workpiece having a first top surface;
forming a pad nitride layer over the workpiece, the pad nitride layer having a second top surface;
forming a sacrificial material over the pad nitride layer, the sacrificial material having a first removal rate;
patterning at least the sacrificial material, the pad nitride layer, and the workpiece to form at least one trench in the sacrificial material, the pad nitride layer, and the workpiece;
filling at least a first portion of the at least one trench with an insulating material, the insulating material having a second removal rate, wherein the second removal rate of the insulating material is slower than the first removal rate of the sacrificial material;
polishing the workpiece to remove the insulating material from over the top surface of the pad nitride layer, wherein at least a substantial amount of the sacrificial material is removed from over the top surface of the pad nitride layer during the polishing process; and
removing at least the pad nitride layer and a portion of the insulating material, the insulating material comprising a third top surface after removing at least the pad nitride layer and the portion of the insulating material, wherein no portion of the third top surface of the insulating material resides beneath the first top surface of the workpiece.

13. The method according to claim 12, wherein filling at least a portion of the at least one trench comprises completely filling the at least one trench with the insulating material.

14. The method according to claim 12, wherein patterning at least the sacrificial material, the pad nitride layer, and the workpiece comprises forming at least one trench having a depth beneath the top surface of the workpiece, and wherein filling at least the first portion of the at least one trench comprises filling the at least one trench by at least ¼ of the depth of the at least one trench.

15. The method according to claim 14, further comprising filling at least a second portion of the at least one trench with the insulating material, after filling at least the first portion of the at least one trench with the insulating material.

16. The method according to claim 15, further comprising etching away the insulating material from an upper rim of the at least one trench, before filling the at least a second portion of the at least one trench.

17. The method according to claim 12, further comprising forming an oxide liner over the workpiece, before forming the layer of nitride material, wherein patterning at least the sacrificial material, the pad nitride layer, and the workpiece to form at least one trench in the sacrificial material and the workpiece further comprises patterning the layer of oxide liner so that the at least one trench is also formed in the oxide liner material.

18. The method according to claim 12, wherein patterning at least the sacrificial material, the pad nitride layer, and the workpiece comprises depositing a layer of photoresist over the sacrificial material, patterning the layer of photoresist using a lithography mask, developing the layer of photoresist, and using the layer of photoresist as a mask to pattern at least the sacrificial material, the pad nitride layer, and the workpiece.

19. The method according to claim 18, further comprising forming a hard mask over at least the sacrificial material, before depositing the layer of photoresist over the sacrificial material, wherein patterning at least the sacrificial material comprises patterning the layer of photoresist using the lithography mask, developing the layer of photoresist, using the layer of photoresist as a mask to pattern the hard mask, and using either the layer of photoresist, the hard mask, or both the layer of photoresist and the hard mask, as a mask to pattern at least the sacrificial material, the pad nitride layer, and the workpiece.

20. The method according to claim 12, wherein the first removal rate is about 5 times or greater than the second removal rate using a chemical mechanical polishing (CMP) process.

21. The method according to claim 12, wherein forming the sacrificial material comprises forming boron phosphate silicate glass (BPSG).

22. The method according to claim 12, wherein all of the sacrificial material is removed from over the top surface of the pad nitride layer during the polishing process.

23. The method according to claim 12, wherein a portion of the sacrificial material is left residing over the top surface of the pad nitride layer after the polishing process, further comprising removing the portion of the sacrificial material, before removing at least the pad nitride layer and the portion of the insulating material.

24. A semiconductor device, comprising:
a workpiece, the workpiece having a first top surface;
a plurality of trenches formed in the workpiece; and
an insulating material disposed in the plurality of trenches, the insulating material comprising a second top surface, the insulating material in the plurality of trenches comprising a plurality of shallow trench isolation (STI) regions, wherein no portion of the second top surface of the insulating material resides below the first top surface of the workpiece.

25. The semiconductor device according to claim 24, wherein the second top surface of the plurality of STI regions extends above the first top surface of the workpiece by a step height of between zero to about 300 Angstroms for each of the plurality of STI regions.

26. The method according to claim 24, wherein each of the plurality of trenches comprises sidewalls and a bottom surface, further comprising a liner disposed over the sidewalls and bottom surface of each of the plurality of trenches.

27. The method according to claim 26, wherein the liner comprises a first liner comprising an oxide having a thickness of about 7 nm or less, and a second liner disposed over the first liner comprising a nitride and having a thickness of about 13 nm or less.
